(19) United States
(12) Patent Application Publication
(10) Pub. No.: US 2006/0060146 A1
(43) Pub. Date: Mar. 23, 2006

(54) Semiconductor manufacturing apparatus and methods

(75) Inventor: Jeong-Min Cha, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/231,244

(22) Filed: Sep. 20, 2005

(30) Foreign Application Priority Data
Sep. 21, 2004 (KR) 2004-75607

(51) Int. Cl. C23C 16/00; H01L 21/306

(52) U.S. Cl. 118/728; 156/345.11

(57) ABSTRACT

A semiconductor manufacturing apparatus for use with a workpiece includes a first structure, a second structure, and a current applying device. The first structure is adapted to hold the workpiece and includes a first coupling member. The second structure includes a second coupling member. The current applying device is adapted to selectively apply a current to at least one of the first and second coupling members to magnetize the at least one of the first and second coupling members such that the first coupling member is magnetically coupled with the second coupling member.

### CROSS-REFERENCE TO RELATED APPLICATION

The present application claims the benefit of priority from Korean Patent Application No. 2004-75607, filed on Sep. 21, 2004, the disclosure of which is hereby incorporated herein by reference in its entirety.

### FIELD OF THE INVENTION

The present invention relates to semiconductor manufacturing apparatus and methods and, more particularly, to semiconductor manufacturing apparatus and methods capable of reducing maintenance and/or application time.

### BACKGROUND OF THE INVENTION

Semiconductor devices are manufactured by processing a wafer. To ensure the reliability of a completely processed wafer, the wafer is tested by applying an electrical signal directly to a semiconductor device formed on the wafer. Such a test is called an electrical die sorting (EDS) test. Further, a semiconductor apparatus for performing an EDS test may be called a wafer probing machine or a wafer test apparatus.

As disclosed in U.S. Pat. No. 6,417,638, entitled “APPARATUS FOR ELECTRICAL TESTING OF A SUBSTRATE HAVING A PLURALITY OF TERMINALS”, a wafer test apparatus aligns a probe card and a holder (vacuum chuck) to measure electrical characteristics of a wafer.

An apparatus for electrically testing wafers includes a test head and a prober. A chuck is mounted on the prober and a wafer is placed on the chuck for testing. The chuck is coupled with a support using a plurality of screws. Thus, in the event that the chuck is replaced due to damage of the chuck or breakage of a hot wire or for maintenance of the apparatus, an operator must loosen the screws.

### SUMMARY OF THE INVENTION

According to embodiments of the present invention, a semiconductor manufacturing apparatus for use with a workpiece includes a first structure, a second structure, and a current applying device. The first structure is adapted to hold the workpiece and includes a first coupling member. The second structure includes a second coupling member. The current applying device is adapted to selectively apply a current to at least one of the first and second coupling members to magnetize the at least one of the first and second coupling members such that the first coupling member is magnetically coupled with the second coupling member.

According to some embodiments of the present invention, the first structure includes a chuck structure including a chuck adapted to support a wafer, the first coupling member is mounted on the chuck, the second structure is a base structure including a stem adapted to support the chuck, and the second coupling member is mounted on the stem.

According to method embodiments of the present invention, a method for manufacturing a semiconductor device includes: mounting a workpiece on a first structure, the first structure including a first coupling member; magnetically coupling the first structure to a second structure including a second coupling member by applying a current to at least one of the first and second coupling members to magnetize the at least one of the first and second coupling members such that the first coupling member is magnetically coupled with the second coupling member; selectively ceasing application of the current to the at least one of the first and second coupling members such that the first and second coupling members are no longer magnetically coupled; and thereafter removing the first structure from the second structure.

Further features, advantages and details of the present invention will be appreciated by those of ordinary skill in the art from a reading of the figures and the detailed description of the preferred embodiments that follow, such description being merely illustrative of the present invention.

### BRIEF DESCRIPTION OF THE DRAWINGS

FIG. 1 is a schematic, cross-sectional view of a semiconductor manufacturing apparatus according to embodiments of the present invention.

FIGS. 2A and 2B are a bottom plan view of a chuck and a top plan view of a stem, respectively, of the apparatus of FIG. 1.

FIGS. 3A and 3B are a bottom plan view of a modified chuck and a top plan view of a modified stem, respectively, of the apparatus of FIG. 1.

FIG. 4 is a perspective view of a wafer test apparatus including the apparatus of FIG. 1.

FIG. 5 is a front view of the wafer test apparatus of FIG. 4.

### DETAILED DESCRIPTION OF EMBODIMENTS OF THE INVENTION

The present invention now will be described more fully hereinafter with reference to the accompanying drawings, in which illustrative embodiments of the invention are shown. In the drawings, the relative sizes of regions or features may be exaggerated for clarity. This invention may, however, be embodied in many different forms and should not be construed as limited to the embodiments set forth herein; rather, these embodiments are provided so that this disclosure will be thorough and complete, and will fully convey the scope of the invention to those skilled in the art.

It will be understood that when an element is referred to as being “coupled” or “connected” to another element, it can be directly coupled or connected to the other element or intervening elements may also be present. In contrast, when an element is referred to as being “directly coupled” or “directly connected” to another element, there are no intervening elements present. Like numbers refer to like elements throughout. As used herein the term “and/or” includes any and all combinations of one or more of the associated listed items.

In addition, spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

Well-known functions or constructions may not be described in detail for brevity and/or clarity.

The terminology used herein is for the purpose of describing particular embodiments only and is not intended to be limiting of the invention. As used herein, the singular forms “a”, “tan” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

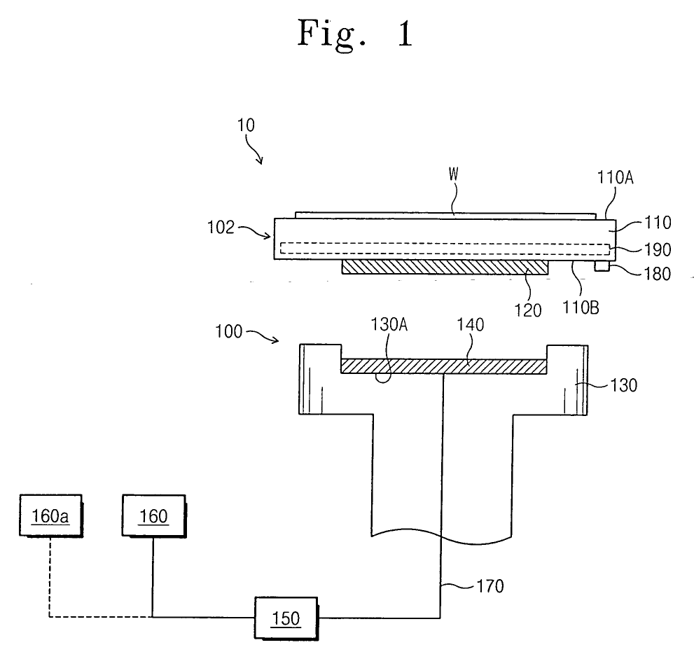

As illustrated in FIG. 1, a semiconductor manufacturing apparatus 10 (e.g., a wafer test apparatus) according to embodiments of the present invention includes a chuck structure 102 on which a wafer W is loaded for testing and a base structure 100 having a stem 130 serving as a support for the chuck structure 102.

The chuck structure 102 includes a chuck 110 having a surface 110A on which the wafer W is placed and an opposing surface 110B to which a coupling member 120 having a prescribed shape is secured for coupling the chuck 110 with the stem 130. A plurality of chips to be electrically tested may be formed on the wafer W. The wafer W may be mounted on the chuck 110 by vacuum, for example.

In some cases, when the wafer W is tested using such a semiconductor manufacturing apparatus, the temperature of the wafer W may be set to a prescribed or desired temperature such as, for example, about 85 or about 35 degrees centigrade based on device characteristics. Heating means 190, for example, including a coil, is further provided in the chuck 110 for controlling the temperature of the chuck 110 and thereby the temperature of the wafer W. In order to heat the wafer W, the chuck 110 is heated using the coil 190 and the heat is applied to the wafer W by heat conduction. Thus, if it is necessary that the wafer W be set to a relatively higher temperature, the chuck 110 is set to a high temperature. On the other hand, if it is necessary that the wafer W be set to a relatively lower temperature, the chuck 110 is set to a low temperature. A temperature sensor 180 may be provided on the chuck 110 for monitoring and/or controlling the temperature of the chuck 110.

The stem 130 has a coupling member 140 for coupling the stem 130 with the chuck 110. The member 140 mounted on and secured to the stem 130. The member 120 mounted beneath the chuck 110 and the member 140 mounted on the stem 130 are selectively coupled to one another by magnetic force.

According to some embodiments and as shown (FIG. 1), the member 140 is an electromagnet and the member 120 is a metal or metal-containing plate made of a material that is magnetizable by a magnetic force of the electromagnet 140. The member 140 is connected to a current applying device 150 through a conductor 170. The device 150 is provided with a switch 160. The member 140 may be magnetized when a current is applied from the current applying device 150 and demagnetized when the current is no longer applied. The member 140 may be made of, for example, steel that can be magnetized.

The switch 160 can be used to selectively turn the current applying device 150 on and off. More particularly, when the switch 160 is turned on (i.e., activated), a current is applied to the member 140 to magnetize the member 140. Thus, the member 140 magnetically attracts the member 120 to tightly fix the chuck 110 to the stem 130. When the switch 160 is turned off (i.e., deactivated), the applied current is ceased or stopped to demagnetize the member 140. The chuck 110 is thereby released from the stem 130.

According to some embodiments, there is at least one switch 160. According to some embodiments in which there is only one switch 160, the switch 160 can be converted from its turned on (i.e., magnetizing) state its turned off (i.e., non-magnetizing) state only by pressing the switch 160 for a predetermined time (e.g., at least two seconds). This may be desired to ensure reliable interlock. Namely, if an operator mistakenly and momentarily touches the switch 160 while the wafer W is being electrically tested, the device 150 will not be turned off and the tight coupling of the chuck 110 and the stem 130 will be retained, thereby preventing test error that may be caused by movement of the chuck 110.

According to some embodiments of the present invention, two spaced apart switches 160 and 160a are provided (FIG. 1). The application of the current to the member 140 is only stopped when the switches 160 and 160a are simultaneously converted to their respective turned off positions or states. If an operator mistakenly touches one of the switches 160, 160a while a wafer W is being electrically tested, tight coupling of the chuck 110 and the stem 130 will be retained, thereby preventing test error that may be caused by movement of the chuck 110.

According to some embodiments, at least an adjacent surface 130A of the stem 130 is made of a material such as a ceramic that is not affected by magnetization to protect the stem 130 from the magnetic force or field of the member 140. For this reason, the surface 110B of the chuck 110 may also be made of a non-magnetizable material such as a ceramic.

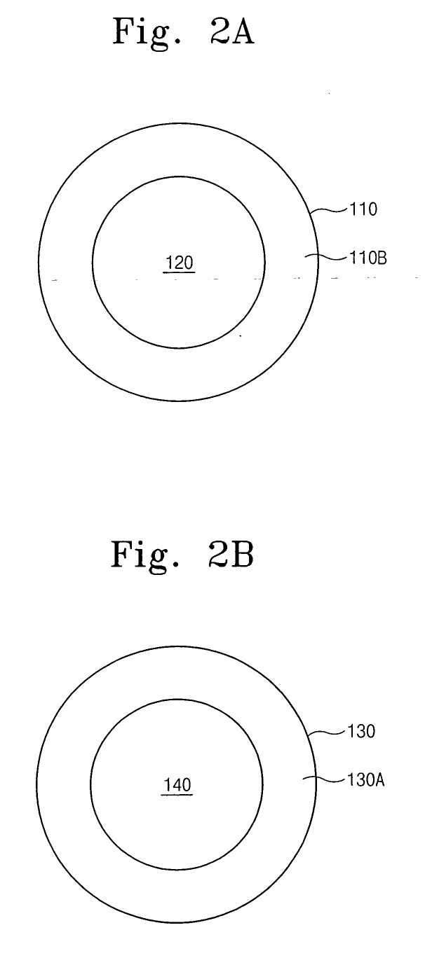

FIG. 2A illustrates a bottom surface of the chuck structure 102 and FIG. 2B illustrates a top surface of the base structure 100. The member 120 mounted on the bottom surface 110A of the chuck 110 may have any shape such as, for example, circular. The member 140 mounted on the top surface 130A of the stem 130 may have any shape and also be circular. If the members 120 and 140 are circular, the chuck 110 need not be oriented in any specific direction when the stem 130 is coupled with the chuck 110.

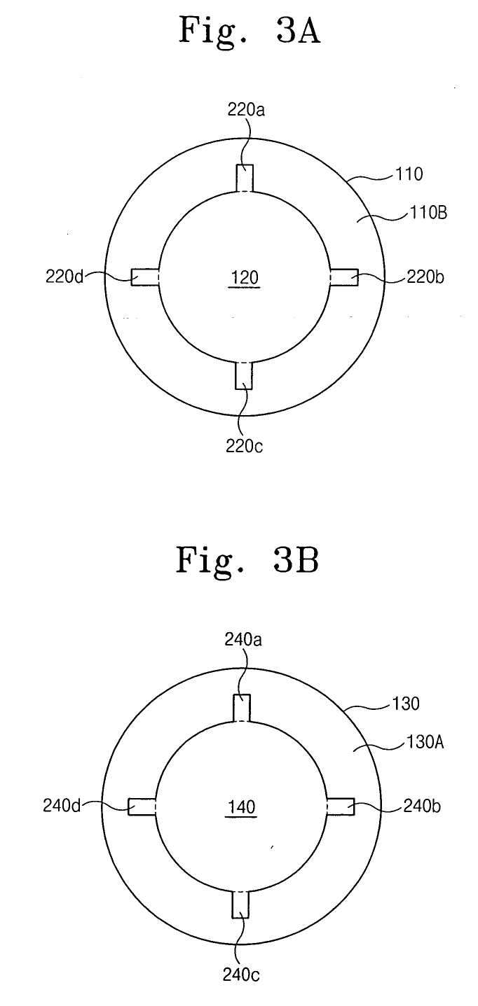

Like FIGS. 2A and 2B, FIG. 3A illustrates a bottom surface of the chuck structure 102 and FIG. 3B illustrates a top surface of base structure 100. The member 120 includes a plurality of (e.g., as shown, four) guides 220a, 220b, 220c, and 220d. The guides 220a, 220b, 220c, 220d are spaced in regular intervals along a circumference of the circular member 120 mounted on the bottom surface of the chuck 110. The guides 220a, 220b, 220c, and 220d serve to guide the relative coupling positioning of the chuck 110 and the stem 130. Although the guides 220a, 220b, 220c, and 220d may have any size and shape, it is desirable that they have the same size and shape in order to readily couple the chuck 110 with the stem 130. The guides 220a, 220b, 220c, and 220d may be made of the same material as the member 120 or of a different material than that of the member 120.

Grooves 240a, 240b, 240c, and 240d are formed in the top surface 130A of the stem 130. The guides 240a, 240b, 240c, and 240d have shapes that are suitable for allowing the guides 220a, 220b, 220c, and 220d to be inserted thereinto, respectively. If the guides 220a, 220b, 220c, and 220d have different sizes and shapes, their corresponding grooves 240a, 240b, 240c, and 240d may have different sizes and shapes. In an exemplary embodiment of the invention, an upper guide 220a is inserted into a corresponding upper groove 240a and a lower guide 220c is inserted into a corresponding lower groove 240c. Similarly, a right guide 220b is inserted into a corresponding right groove 240b and a left guide 220d is inserted into a corresponding left groove 240d.

Alternatively, according to some embodiments, the guides 220a, 220b, 220c, and 220d have the same size and shape, and the grooves 240a, 240b, 240c, and 240d also have the same size and shape. Accordingly, the upper guide 220a may be inserted into any one (e.g., the lower groove 240c) of the grooves 240a, 240b, 240c, and 240d.

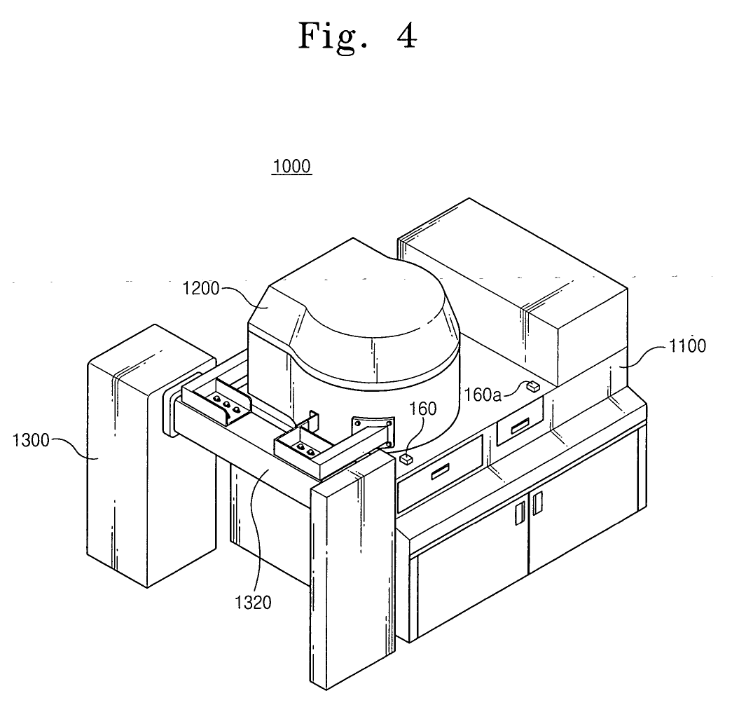

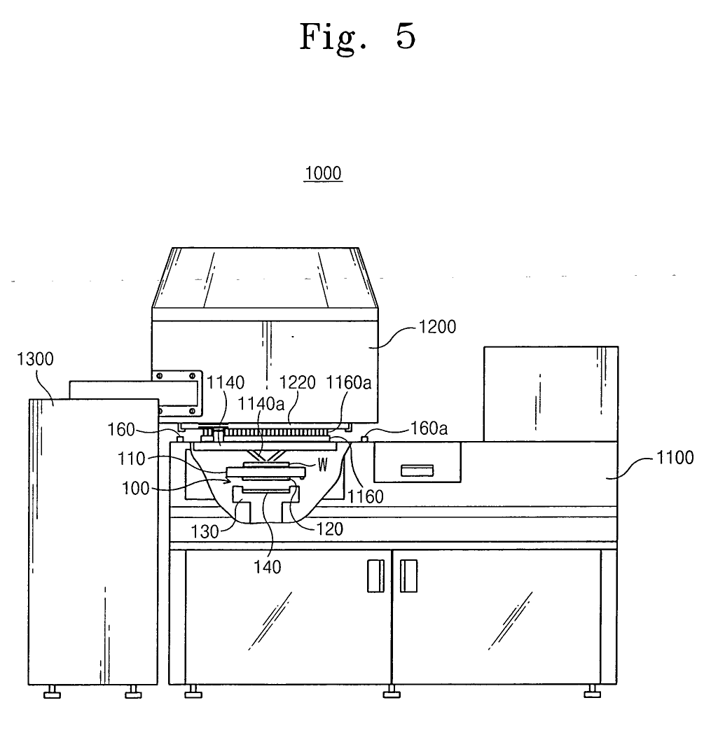

FIG. 4 and FIG. 5 illustrate a wafer test apparatus 1000 including the apparatus 10 as described above. The wafer test apparatus 1000 includes a tester 1200, a prober 1100, and a manipulator 1300. The apparatus 1000 may be used to test the wafer W, for example.

The manipulator 1300 allows the tester 1200 to swing or move up and down from a top surface of the prober 1100 and controls the docking/undocking location and height of the tester 1200. A program for testing wafers is input to the manipulator 1300, and the manipulator 1300 applies an electrical signal to the tester 1200. The tester 1200 is fixed to a driving shaft 1320 of the manipulator 1300.

The tester 1200 generates an electrical signal to apply the signal to each semiconductor device of the wafer W. The tester 1200 includes a performance board 1220, a pogo block 1160, and a probe card 1140. The performance board receives an electrical signal from the manipulator 1300. The pogo block 1160 has a plurality of pogo pins 1160a to which an electrical signal is applied from the performance board 1220. The probe card 1140 connects a plurality of probes 1140a to a substrate. Further, the probe card 1140 allows the electrical signal generated from the tester 1200 to contact a pad of a chip formed on the wafer W to transmit the electrical signal to each device.

The prober 1100 loads and aligns the wafer W for proper contact with the probe 1140. The apparatus 10 is incorporated into the prober 1100 and includes the chuck 110 having the member 120 and the stem 130 having the member 140. The members 120 and 140 are coupled and decoupled by a magnetic force as discussed above. The switches 160 and 160a are disposed on the prober 1100, e.g., on the left and right sides of the tester 1200. The switches 160, 160a can be used to turn the power device 150 (FIG. 1) on and off to apply a current to the member 140. Alternatively, only one switch 160 may be disposed thereat as discussed above.

The operation of the wafer test apparatus 1000 including the foregoing apparatus 10 will now be described below.

The wafer W to be tested is loaded on the chuck 110. The chuck 110 rises upward toward the probe 1140a of the probe card 1140. Thus, the probe 1140a contacts a pad of each semiconductor device on the wafer W. An electrical signal for testing is applied from the manipulator 1300 under this state. The test signal is transmitted to the probe card 1140 through the tester 1200 to test a normal operation state of each semiconductor device. Because a current continues to flow to the member 140 of the stem 130 supporting the chuck 110 during the test, the member 120 underlying the chuck 110 is magnetically coupled with the member 140 of the stem 130 by magnetic force or field generated by the electromagnet 140.

In testing the wafer W using the wafer test apparatus 1000, it may be necessary or desirable to control the temperature of the wafer W (e.g., 85 or 30 degrees centigrade) based on device characteristics. If the test temperature is 85 degrees centigrade, the chuck 110 is heated by the heating means 190 installed in the chuck 110 to transfer heat to the wafer W. The wafer W can thereby be heated to the appropriate temperature (e.g., 85 degrees centigrade) during the test.

If it is necessary or desirable to test the wafer W at a second, different temperature such as room temperature after testing the wafer at the first temperature (e.g., a higher temperature such as 85 degrees centigrade), the switches 160 and 160a are turned off to cease the application of current to the member 140. The member 140 is thereby demagnetized. As discussed above, in the event that there are two switches 160 and 160a, they must be turned off at the same time to cease current. In the event that there is only one switch 160, a current is preferably ceased only if the switch is pressed for a predetermined time (e.g., at least 2 seconds).

Once the current has been stopped to demagnetize the member 140, the chuck structure 102 is removed or disassembled from the stem 130. A new chuck structure 102 including a new chuck 110 at a different temperature such as room temperature (e.g., 30 degrees centigrade) is mounted on the stem 130 and a current is applied by the device 150 to magnetize the member 140. Thus, the new chuck 110 is tightly fixed to the stem 130 by the magnetic coupling in the same manner as the first chuck 110. Because the new chuck 110 is at the new temperature such as room temperature, there is no time required for cooling a chuck from the first, relatively higher high temperature (e.g., 85 degrees centigrade) to the second, relatively lower temperature such as room temperature. Similarly, a chuck structure 100 including a relatively cool (e.g., room temperature) chuck 110 can be replaced in the same manner with a chuck structure 100 including a relatively hot pre-heated (e.g., about 85 degrees centigrade) chuck 110 if needed or desired. In either case, the time required for changing the temperature of the chuck supporting the wafer can be significantly reduced.

As will be appreciated from the foregoing description, disassembly and assembly of the chuck structure 102 from the base structure 100 for maintenance of the apparatus 10 can be readily accomplished by turning the switch 100 (or the switches 160 and 160a) on and off to apply a current and stop applying the current to the electromagnet 140. Accordingly, there is no need for work such as unscrewing to disassemble the chuck 110 from the stem 130.

The above-described magnetic assembling (coupling) and disassembling are not limited to a chuck assembly and may be applied to any apparatus using a screw or the like. For example, an electromagnetic coupling according to the invention may be used to assemble and disassemble a cleaning unit which needs to be opened, to replace parts of a prober stage, to replace a sanding paper, or to assemble and disassemble a pogo block when pogo pins are broken or in need of cleaning.

According to embodiments of the present invention, parts of an apparatus can be replaced using a one-touch method to reduce effort and loss of time. Further, when a chuck temperature change is needed or desired, a spare chuck having a preset temperature can be used to achieve a fast change in temperature of a chuck supporting a wafer.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the invention.

1. A semiconductor manufacturing apparatus for use with a workpiece, the apparatus comprising:
a first structure adapted to hold the workpiece and including a first coupling member; and
a second structure including a second coupling member; and
a current applying device adapted to selectively apply a current to at least one of the first and second coupling members to magnetize the at least one of the first and second coupling members such that the first coupling member is magnetically coupled with the second coupling member.

2. The apparatus of claim 1 wherein the first structure has first and second opposing surfaces, wherein the first surface is adapted to hold the workpiece and the first coupling member is mounted on the second surface.

3. The apparatus of claim 1 further comprising a switch adapted to selectively turn the current applying device on and off.

4. The apparatus of claim 3 wherein the switch is adapted to maintain the current applying device in a turned off state until the switch has been actuated for at least a prescribed period of time.

5. The apparatus of claim 3 including a second switch, wherein the first and second switches are adapted to maintain the current applying device in a turned off state until the first and second switches have been simultaneously actuated.

6. The apparatus of claim 1 wherein at least one of the first and second coupling members is adapted to become an electromagnet when a current is applied thereto.

7. The apparatus of claim 6 wherein at least one of the first and second coupling members is made of steel.

8. The apparatus of claim 1 wherein at least one of the first and second structures includes a body portion that is not magnetizable.

9. The apparatus of claim 8 wherein the body portion is made of a ceramic.

10. The apparatus of claim 1 wherein:
the first structure includes a chuck structure including a chuck adapted to support a wafer;
the first coupling member is mounted on the chuck;
the second structure is a base structure including a stem adapted to support the chuck; and
the second coupling member is mounted on the stem.

11. The apparatus of claim 10 wherein the chuck has a top surface adapted to support the wafer and an opposing bottom surface on which the first coupling member is mounted.

12. The apparatus of claim 10 further comprising a switch adapted to selectively turn the current applying device on and off.

13. The apparatus of claim 12 wherein the switch is adapted to maintain the current applying device in a turned off state until the switch has been actuated for at least a prescribed period of time.

14. The apparatus of claim 12 including a second switch, wherein the first and second switches are adapted to maintain the current applying device in a turned off state until the first and second switches have been simultaneously actuated.

15. The apparatus of claim 10 wherein at least one of the first and second coupling members is adapted to become an electromagnet when a current is applied thereto.

16. The apparatus of claim 10 wherein the first coupling member includes a first metal plate and the second coupling member includes a second metal plate.

17. The apparatus of claim 16 wherein at least one of the first and second metal plates is made of steel.

18. The apparatus of claim 10 wherein at least one of the chuck and the stem is not magnetizable.

19. The apparatus of claim 18 wherein at least one of the chuck and the stem is made of a ceramic.

20. The apparatus of claim 10 wherein the chuck structure includes a heating device mounted on the chuck.

21. The apparatus of claim 10 wherein the chuck structure includes a temperature sensor adapted to sense a temperature of the chuck.

22. The apparatus of claim 10 wherein the first and second structures each have a side opposing the other and include first and second cooperating guide structures, respectively, on their opposing sides to guide mating of the chuck with the stem.

23. The apparatus of claim 22 wherein:
the first guide structure includes a guide projection extending from a bottom surface of the chuck;
the second guide structure includes a groove defined in a top surface of the stem and adapted to receive the guide projection;
the first coupling member is mounted on the bottom surface of the chuck; and
the second coupling member is mounted on the top surface of the stem.

24. The apparatus of claim 23 including a plurality of guide projections extending from the bottom surface of the chuck and a plurality of grooves defined in the top surface of the stem and adapted to receive the guide projections.

25. The apparatus of claim 24 wherein the first coupling member is circular and the guide projections are spaced apart at regular intervals about the circumference of the first coupling member.

26. The apparatus of claim 10 including at least one device adapted to test electrical characteristics of a semiconductor device formed on a wafer when the wafer is mounted on the chuck.

27. A method for manufacturing a semiconductor device, the method comprising:
mounting a workpiece on a first structure, the first structure including a first coupling member;
magnetically coupling the first structure to a second structure including a second coupling member by applying a current to at least one of the first and second coupling members to magnetize the at least one of the first and second coupling members such that the first coupling member is magnetically coupled with the second coupling member;
selectively ceasing the application of the current to the at least one of the first and second coupling members such that the first and second coupling members are no longer magnetically coupled; and thereafter
removing the first structure from the second structure.

28. The method of claim 27 wherein the first structure includes a chuck adapted hold the wafer and the second structure includes a stem adapted to support the chuck.

29. The method of claim 28 further including, after removing the first structure from the second structure:
mounting the workpiece on a third structure, the third structure including a second chuck and a third coupling member; and
magnetically coupling the third structure to the second structure by applying a current to at least one of the third and second coupling members to magnetize the at least one of the third and second coupling members such that the third coupling member is magnetically coupled with the second coupling member.

30. The method of claim 29 wherein the second chuck has a prescribed temperature that is different than a temperature of the first chuck.
